(19) United States
(12) Patent Application Publication
(10) Pub. No.: US 2025/0253669 A1
(43) Pub. Date: Aug. 7, 2025

(54) ELECTRICITY STORAGE SYSTEM

(71) Applicant: TOYOTA JIDOSHA KABUSHIKI KAISHA, Toyota-shi (JP)

(72) Inventor: Akinori MORISHIMA, Naka-gun (JP)

(73) Assignee: TOYOTA-SHI JIDOSHA KABUSHIKI KAISHA, Toyota-shi (JP)

(21) Appl. No.: 18/945,570

(22) Filed: Nov. 13, 2024

(30) Foreign Application Priority Data
Feb. 6, 2024 (JP) 2024-016346

(51) Int. Cl. H02J 3/32; B60L 53/20; B60L 55/00; G01R 31/382; H02J 3/00; H02J 3/46; H02J 7/00

(52) U.S. Cl. CPC H02J 3/322; B60L 53/20; B60L 55/00; G01R 31/382; H02J 3/003; H02J 3/466; H02J 7/00032; H02J 2203/20; H02J 2310/14

(57) ABSTRACT

The power storage system is a system including a power storage device provided in a facility such as a house that is supplied with purchased power from a power system such as a power grid, a power demand device (an air conditioner, a heat pump water heater, a charging/discharging device, an electrified vehicle) that is different from the power storage device, and HEMS controllers that manage the use of power in the power storage device and the power demand device. HEMS controllers comprise a processor, such as a CPU of controls. The processor controls the power storage device to charge the power storage device when the remaining capacity stored in the power storage device is equal to or less than a predetermined value after limiting the use of the purchased power in the demand device.

### CROSS-REFERENCE TO RELATED APPLICATION

This application claims priority to Japanese Patent Application No. 2024-016346 filed on Feb. 6, 2024, incorporated herein by reference in its entirety.

### BACKGROUND

### 1. Technical Field

The present disclosure relates to an electricity storage system, and more particularly, to an electricity storage system including an electricity storage device provided in a facility that receives supply of electricity from an electricity system, an electricity demanding device that is different from the electricity storage device, and a management device that manages use of electricity in the electricity storage device and the demanding device.

### 2. Description of Related Art

There has been conventionally an electricity storage system that is provided in a house and includes a fixed storage battery that stores commercial electricity and electricity generated by an electricity generation device such as a solar battery (for example, refer to Japanese Unexamined Patent Application Publication No. 2019-062618 (JP 2019-062618 A)). In such a house, the basic charge may be determined according to the peak electricity of the purchased electricity in the house in the electricity purchase contract of the commercial electricity. In this case, the purchased electricity is used so as not to exceed the peak electricity in the house. In the electricity storage device of JP 2019-062618 A, an electrified vehicle may be charged in a house. In this case, the fixed storage battery is charged in advance by electricity that is expected to exceed the peak electricity at the time of charging the electrified vehicle based on the information of the estimated time of returning home of electrified vehicle.

### SUMMARY

In the technique of JP 2019-062618 A, when charging the fixed storage battery in advance, there is a concern that an amount of electricity required for the fixed storage battery cannot be charged in the case where there is a large electricity demand from other devices provided in a facility such as a house.

The present disclosure provides an electricity storage system capable of storing more electricity in an electricity storage device in preparation for peak shaving of purchased electricity in a facility.

The electricity storage system according to the present disclosure includes: an electricity storage device that is provided in a facility that receives supply of purchased electricity from an electricity system, an electricity demanding device that is different from the electricity storage device, and a management device that manages use of electricity in the electricity storage device and the demanding device.

The management device includes a processor.
The processor performs control such that the electricity storage device is charged when a remaining capacity stored in the electricity storage device is equal to or less than a predetermined value after use of the purchased electricity in the demanding device is restricted.

According to such a configuration, the electricity storage device is charged when the remaining capacity stored in the electricity storage device is equal to or less than a predetermined value after the use of the purchased electricity in the electricity demanding device that is different from the electricity storage device provided in the facility is restricted. As a result, it is possible to provide an electricity storage system capable of storing more electricity in the electricity storage device in preparation for the peak shaving of the purchased electricity in the facility.

The processor may perform control such that the use of the purchased electricity in the demanding device is restricted when a peak shaving of the purchased electricity is required at the facility.

According to such a configuration, it is possible to more reliably store more electricity in the electricity storage device in preparation for the peak shaving of the purchased electricity in the facility.

The processor may perform control such that the electricity storage device is charged in a case where the electricity demand in the demanding device is less than a predetermined first electricity and in a case where the remaining capacity stored in the electricity storage device is equal to or less than a predetermined value after the use of the purchased electricity in the demanding device is restricted.

According to such a configuration, it is possible to more reliably store more electricity in the electricity storage device in preparation for the peak shaving of the purchased electricity in the facility.

The processor may perform control such that electricity is discharged from the electricity storage device when the electricity demand in the demanding device is equal to or higher than a predetermined second electricity equal to or greater than the predetermined first electricity after the use of the purchased electricity in the demanding device is restricted.

According to such a configuration, it is possible to appropriately supply electricity to the demanding device even when the use of the purchased electricity in the demanding device is restricted.

The processor may perform control such that the electricity storage device is charged when the peak shaving of electricity consumption is not required in the facility, when the electricity storage device needs to be charged, when the electricity demand in the demanding device is not less than a predetermined third electricity, and when the electricity demand in the demanding device becomes less than the predetermined third electricity after performing control to restrict the use of the purchased electricity in the demanding device.

According to such a configuration, it is possible to store more electricity in the electricity storage device in preparation for the peak shaving of the purchased electricity in the facility.

According to the present disclosure, it is possible to provide an electricity storage system capable of storing more electricity in an electricity storage device in preparation for a peak shaving of purchased electricity in a facility.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram schematically illustrating an overall configuration of a power system according to this embodiment;

FIG. 2 is a flowchart showing the flow of the peak cut-related processing of this embodiment;

FIG. 3 is a graph showing changes in electric power used in a conventional house;

FIG. 4 is a graph showing a change in electric power used in a house after measures in this embodiment;

FIG. 5A is a diagram illustrating a change in a reduction in power consumed by an electric device; and

FIG. 5B is a diagram illustrating a change in an SOC of a power storage device.

### DETAILED DESCRIPTION OF EMBODIMENTS

Hereinafter, embodiments of the present disclosure will be described in detail with reference to the drawings. It should be noted that the same or corresponding portions in the drawings are designated by the same reference signs and repetitive description will be omitted.

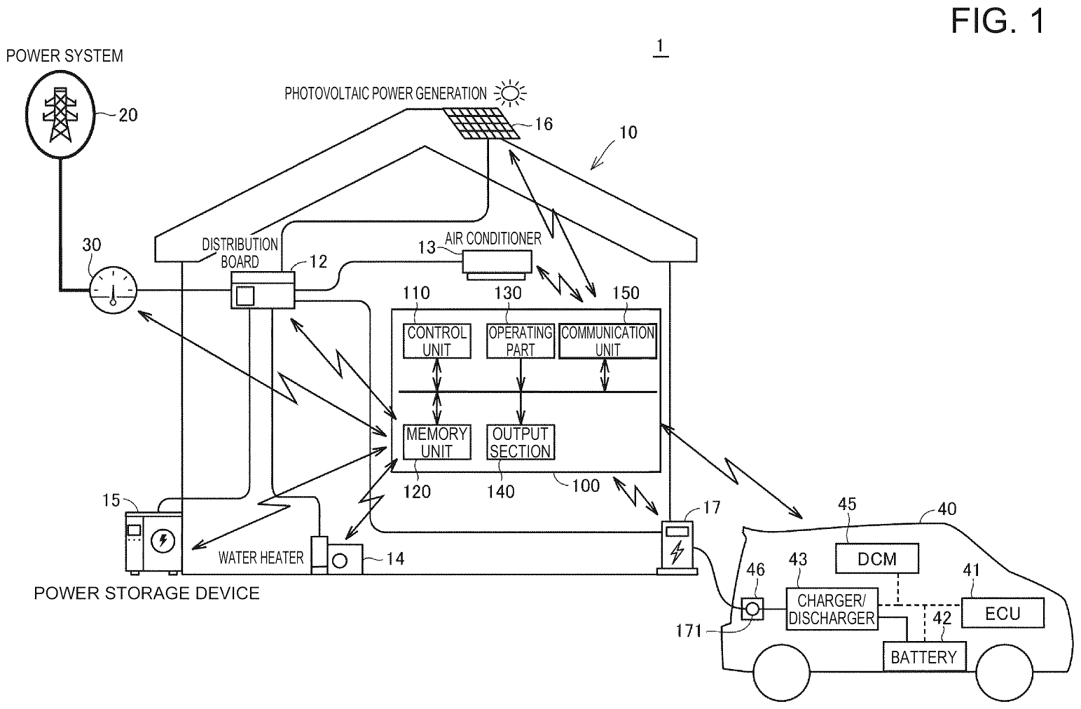

FIG. 1 is a diagram schematically illustrating an overall configuration of a power system 1 according to this embodiment. As shown in FIG. 1, the power system 1 includes a house 10, a power grid 20, a smart meter 30, an electrified vehicle 40, and HEMS (Home Energy Management System) controllers 100.

The electric power grid 20 is an electric power system including a power plant, a power transmission line, a substation, a distribution line, and the like, and is an electric power grid managed by an electric power retailer or the like. The power grid 20 and the in-house power line of the house 10 are connected via a smart meter 30. The smart meter 30 is an electronic watt-hour meter having a communication function. The smart meter 30 measures the amount of electric power exchanged between the electric power grid 20 and the house 10, and transmits the measured amount of electric power to servers such as electric power retailers together with identification (ID) code of the smart meter 30 at predetermined intervals.

In the house 10 connected to the electric power grid 20 via the smart meter 30, various electric devices are connected via the power distribution board 12 using an in-house power line. Examples of the various electric apparatuses include an air conditioner 13, a heat pump water heater 14, a power storage device 15, a photovoltaic power generation device 16, and a charging/discharging device 17. As a result, the electric power supplied from the electric power grid 20 can be consumed by these electric devices, and the electric power generated by the photovoltaic power generation device 16 and the electric power discharged from electrified vehicle 40 can be supplied to the electric power grid 20 (reverse power flow).

In the charging/discharging device 17, the connector 171 at the distal end of the cable is connected to the inlet 46 of electrified vehicle 40. Accordingly, the charging/discharging device 17 can charge electrified vehicle 40 battery 42 and reverse flow the electric power discharged from electrified vehicle 40 to the electric power grid 20.

Electrified vehicle 40 is a battery electric vehicle (BEV: Battery Electric Vehicle) equipped with a battery 42. However, the types of electrified vehicle 40 may be any types as long as they can be connected to the charging/discharging device 17. Electrified vehicle 40 may be plug-in hybrid electric vehicle (PHEV: Plug-in Hybrid Electric Vehicle) or a pluggable fuel cell electric vehicle (FCEV: Fuel Cell Electric Vehicle).

Electrified vehicle 40 includes ECU (Electronic Control Unit) 41, DCM (Data Communication Module) 45, a battery 42, a charger/discharger 43, and an inlet 46.

The battery 42 includes a secondary battery capable of charging and 20 discharging electric power such as a lithium-ion battery or a nickel metal hydride battery, and a monitoring unit for the secondary battery. The monitoring unit monitors the status of the secondary batteries (e.g., voltage, current, temperature, etc.) and sends the monitoring to ECU 41.

The inlet 46 is connectable to a connector for charging and discharging, 25 such as the connector 171 of the charging/discharging device 17, and receives electric power supplied from the outside and outputs electric power of the battery 42 to the outside.

During charging, the charger/discharger 43 converts alternating current power input to the inlet 46 into direct current power and charges the battery 42, while during discharging, converting direct current power of the battery 42 into alternating current power and discharging the alternating current power from the inlet 46.

DCM 45 wirelessly transmits information such as data from an ECU 41 or the like to an external device, or transmits information such as data wirelessly transmitted from an external device to an ECU 41 or the like.

ECU 41 includes a processor such as CPU (Central Processing Unit) and memories, and controls the whole including electrified vehicle 40 charger/discharger 43, DCM 45, and the drive system.

HEMS controllers 100 include a control unit 110, a storage unit 120, an operation unit 130, an output unit 140, and a communication unit 150, and manage the use of electric power in electric devices of the house 10. The output unit 140 includes a display and a speaker. The operation unit 130 includes a touch panel and other operation buttons formed on the surface of the screen of the display. The communication unit 150 has a communication function for wirelessly or wirelessly communicating with an external device. The storage unit 120 includes a memory and stores programs and data used in the control unit 110. The control unit 110 includes a CPU as a processor, and processes data from the storage unit 120 or the communication unit 150 or operation information on the operation unit 130, and outputs the processing result to the output unit 140, the storage unit 120, or the communication unit 150.

In the house 10 provided with the power storage system including the power storage device 15 as described above, the basic charge may be determined in accordance with the peak power of the purchased power in the house 10 in the commercial power purchase contract. In this case, the purchased electric power is used in the house 10 so as not to exceed the peak electric power. In the power storage device, electrified vehicle 40 may be charged in the house 10. In this case, the power storage device 15 is charged in advance with a portion that is expected to exceed the peak power at the time of charging electrified vehicle 40 based on the information on the estimated time of returning home of electrified vehicle 40. When the power storage device 15 is charged in advance, there is a concern that the amount of electric power required for the power storage device 15 cannot be charged in a case where the demand for electric power of another electric device provided in a facility such as the house 10 is large.

Therefore, the power storage system is provided in a facility such as the house 10 that is supplied with purchased electric power from an electric power system such as the electric power grid 20. The power storage system includes a power storage device 15, a power demand device that differs from the power storage device 15, and a HEMS controller 100 that manages use of power in the power storage device 15 and the power demand device. HEMS controllers 100 include CPU of the control unit 110. CPU of the control unit 110 controls to charge the power storage device 15 when the remaining capacity stored in the power storage device 15 is equal to or less than a predetermined value after limiting the use of the purchased power in the demand device.

Thus, the power storage device 15 is charged when the remaining capacity stored in the power storage device 15 is equal to or less than a predetermined value after restricting the use of the purchased power in the device having a power different from the power storage device 15 provided in the facility. As a result, more electric power can be stored in the power storage device 15 in preparation for the peak cut of the purchased electric power in the facility.

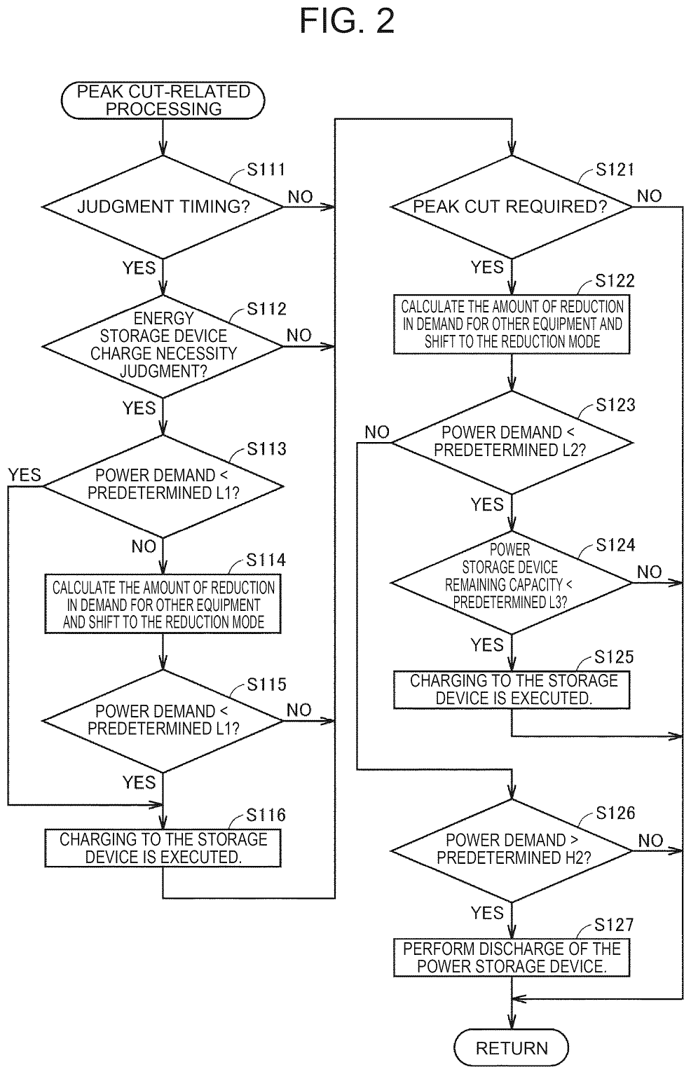

FIG. 2 is a flowchart illustrating a flow of peak cut-related processing according to the present embodiment. Referring to FIG. 2, the peak-cut related processing is called from the higher-order processing by CPU of the control unit 110 of HEMS controller 100 and is executed.

First, CPU of the control unit 110 determines whether the present is the determination timing at every predetermined cycle (S111). When it is determined that it is the determination timing (YES in S111), CPU determines whether the power storage device 15 needs to be charged (S112). This determination is made, for example, by determining whether SOC or the remaining electric power amount of the power storage device 15 is less than the predetermined value L0, determining that charging is required when the remaining electric power amount is less than the predetermined value L0, and determining that charging is not necessary when the remaining electric power amount is equal to or greater than the predetermined value L0.

When it is determined that the power storage device 15 needs to be charged (YES in S112), CPU of the control unit 110 determines whether or not the total power demand of the electric devices other than the power storage device 15 in the house 10 is less than the predetermined value L1 (S113). When it is determined that the power demand is not less than the predetermined value L1 (NO in S113), CPU calculates a demand reduction amount that can be reduced by another electric device other than the power storage device 15. CPU shifts the control status of the other electric appliance to the reduction mode in which the power demand of the calculated demand reduction amount is reduced (S114).

Next, it is determined whether or not the power demand of the sum of the other electric devices is less than the predetermined value L1 as a result of the control in S114 (S115). When it is determined that the power demand is less than the predetermined value L1 in S115 (YES in S115), and when it is determined that the power demand is less than the predetermined value L1 in S113 (YES in S113), CPU of the control unit 110 controls the power distribution board 12 and the power storage device 15 so as to execute the charge to the power storage device 15 (S116).

When it is determined that the power storage device is not the determination timing (NO in S111) or when it is determined that the power storage device 15 does not need to be charged (NO in S112), CPU of the control unit 110 determines whether or not it is a time when peak-cut is required to reduce the peak power of the purchased electric power currently (S121). If it is determined in S115 that the power demand is no longer less than the predetermined value L1 (NO in S115), or after S116, CPU of the control unit 110 determines whether the peak-cut time in which the peak-power of the purchased power is currently needed to be reduced is S121. The time when the peak cut is required is a time period in which it is highly likely that all the electric power demand in the facility such as the house 10 exceeds the peak electric power of the commercial electric power purchase contract. The time when the peak cut is required is, for example, a time period in which the power demand has reached a predetermined ratio (for example, 80%) or more of the peak power in the past predetermined period (for example, the past year).

When it is determined that the peak cut is required (YES in S121), CPU of the control unit 110 calculates a demand reduction that can be reduced by another electric device other than the power storage device 15. Then, CPU of the control unit 110 shifts the control status of the other electric device to the reduction mode in which the power demand of the calculated demand reduction amount is reduced (S122).

Next, it is determined whether or not the power demand of the sum of the other electric devices is less than the predetermined value L2 as a result of the control in S122 (S123). When it is determined that the power demand is less than the predetermined value L2 (YES in S123), CPU of the control unit 110 determines whether the remaining power amount (remaining capacity) of the power storage device 15 is less than the predetermined value L3 (S124). When it is determined that the remaining capacity is less than the predetermined value L3 (YES in S124), CPU controls the power distribution board 12 and the power storage device 15 so as to charge the power storage device 15 (S125).

On the other hand, when it is determined that the power demand is not less than the predetermined value L2 (NO in S123), CPU of the control unit 110 determines whether the power demand exceeds the predetermined value H2 (≥L2) (S126). When it is determined that the power demand exceeds the predetermined value H2 (YES in S126), CPU controls the power distribution board 12 and the power storage device 15 so as to execute discharging from the power storage device 15 to another electric device (S127).

When it is determined that the peak cut is not required (NO in S121), or when it is determined that the remaining capacity of the power storage device 15 is not less than the predetermined value L3 (NO in S124), CPU of the control unit 110 returns the processing to be executed to the processing higher than the caller of the peak cut related processing. After S125, when it is determined that the power demand does not exceed the predetermined value H2 (NO in S126), or after S127, CPU of the control unit 110 returns the processing to be executed to the processing of the upper level of the caller of the peak cut-related processing.

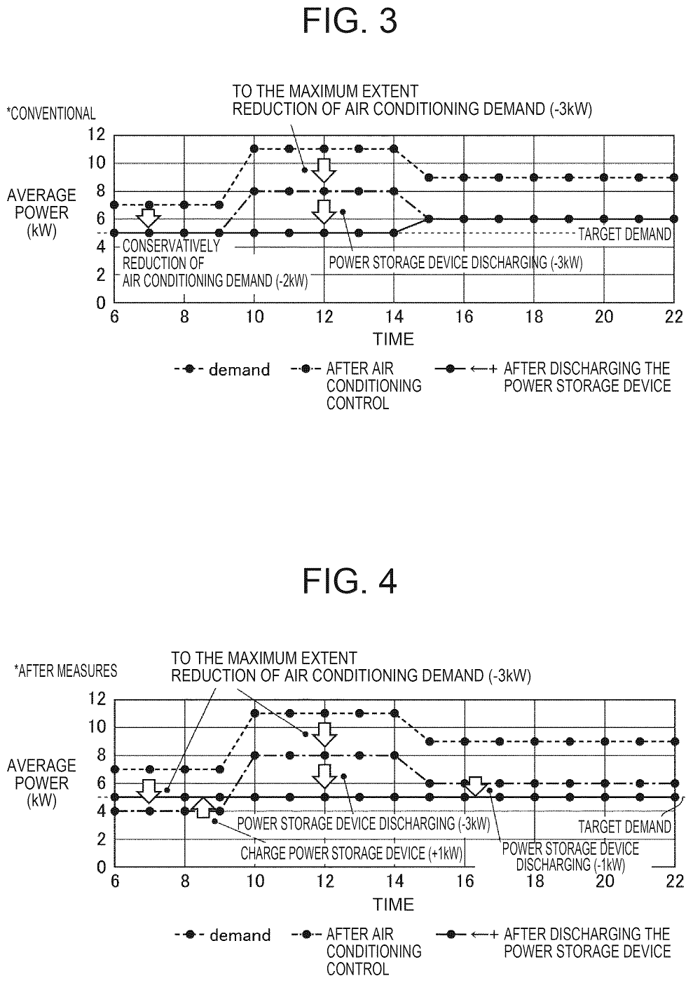

FIG. 3 is a graph showing a change in electric power used in the conventional house 10. Referring to FIG. 3, the horizontal axis represents time, and the vertical axis represents average power in each time period. The broken line indicates the power used in the house 10 when the power demand is not reduced. The dashed-dotted line indicates the power used in the house 10 when the power demand of the air conditioner 13 is reduced. The solid line indicates the electric power used in the house 10 when the electric power demand of the air conditioner 13 is reduced and the electric power is discharged from the power storage device 15.

Conventionally, for example, from 6 o'clock to 9 o'clock, the power demand of the air conditioner 13 is reduced conservatively (e.g., −2 kW). As a result, the mean power demand in the electric appliances of the house 10 decreases from 7 kW to 5 kW.

From 10:00 to 14:00, the mean power demand is increased to a 11 kW, thus maximizing (e.g., −3 kW) the power demand of the air conditioner 13. As a result, the mean power demand in the electric appliances of the house 10 becomes 8 kW. Further, by discharging (e.g., 3 kW) from the power storage device 15, the average power demand of the house 10 becomes a 5 kW of the target demand.

After 15:00, the mean power demand is reduced to 9 kW to maximize (e.g., −3 kW) the power demand of the air conditioner 13. As a result, the mean power demand in the electric appliances of the house 10 becomes 6 kW. However, since the remaining capacity of the power storage device 15 is exhausted and cannot be discharged from the power storage device 15, it is not possible to reduce to 5 kW of the target demand.

FIG. 4 is a graph showing a change in the electric power used in the house 10 after the countermeasure in this embodiment. Referring to FIG. 4, the horizontal axis, the vertical axis, and the line types are the same as those in FIG. 3. For example, from 6 o'clock to 9 o'clock, it is determined in S121 of FIG. 2 that peak-cut is required, and S122 is executed to maximize (e.g., −3 kW) the power demand of the air conditioner 13. Here, it is determined that the power demand is 4 kW and the power demand is less than the predetermined value L2 (=5 kW) which is the target demand in S123 of FIGS. 2, and S125 is executed, whereby charging of the power storage device 15 (charging of 1 kW which is the difference between the power demand and the target demand in this case) is executed.

From 10:00 to 14:00, the mean power demand is increased to 11 kW to maximize (e.g., −3 kW) the power demand of the air conditioner 13. As a result, the mean power demand in the electric appliances of the house 10 becomes 8 kW. Further, by discharging (for example, 3 kW) from the power storage device 15, the average power demand of the house 10 becomes a 5 kW of the target demand.

After 15:00, the mean power demand is reduced to 9 kW, but it is determined in S121 of FIG. 2 that the peak-cut time is required, and S122 is executed to maximize (e.g., −3 kW) the power demand of the air conditioner 13. As a result, the demand for electric power in the electric appliances of the house 10 becomes 6 kW. Here, in S123 of FIG. 2, it is determined that the power demand is not less than the predetermined value L2 (=5 kW) which is the target demand, and in S126, it is determined that the power demand exceeds the predetermined value H2 (=5 kW), and when S127 is executed, discharge from the power storage device 15 (in this case, discharge of 1 kW which is a difference between the power demand and the target demand) is executed. As a result, the average power demand of the house 10 is a 5 kW of the target demand. In this case, since the charging of the power storage device 15 is performed between 6 o'clock and 9 o'clock, there is a margin in the remaining capacity of the power storage device 15, so that the discharging can be continued from the power storage device 15 until 22 o'clock.

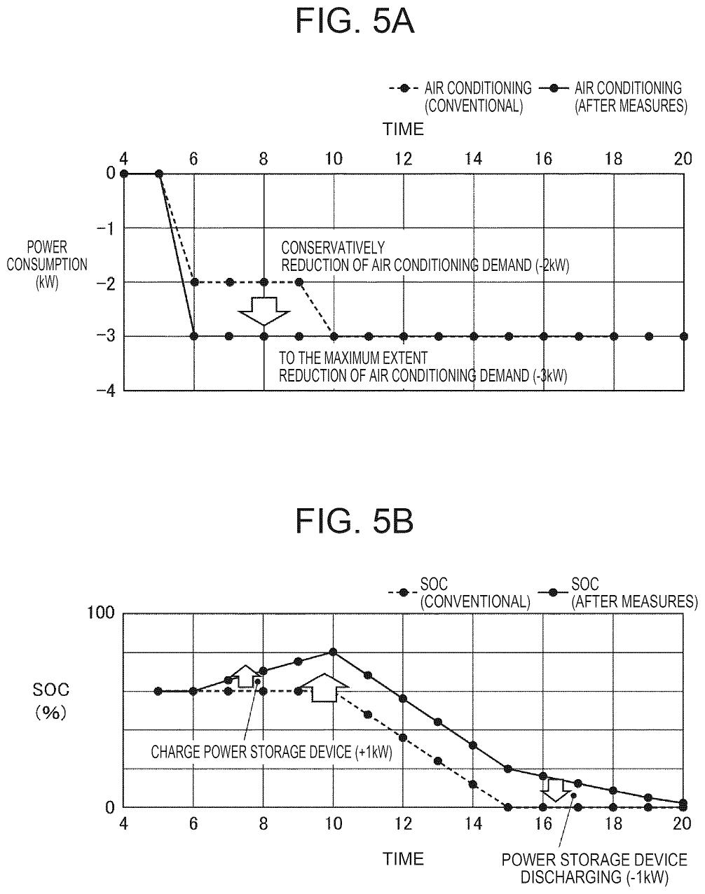

FIGS. 5A and 5B are diagrams illustrating a change in the amount of reduction in power consumed by an electric device and a change in SOC of a power storage device 15. Referring to FIG. 5A, the horizontal axis represents time, and the vertical axis represents a reduction in power consumed by the electric device. The broken line indicates a change in the amount of reduction in the power consumption of the conventional air conditioner 13. The solid line indicates a change in the amount of reduction in the power consumption of the air conditioner 13 after the measures of this embodiment. As shown in FIGS. 3 and 4, conventionally, the reduction in the electric power demand of the air conditioner 13 is made conservative (for example, −2 kW) between 6 o'clock and 9 o'clock, and is made to be maximum (for example, −3 kW) after 10 o'clock. After the countermeasures in this embodiment, the reduction in the power demand of the air conditioner 13 is set to the maximum (for example, −3 kW) after 6 o'clock.

Referring to FIG. 5B, the horizontal axis represents time, and the vertical axis represents SOC of the power storage device 15. The broken line indicates a change in SOC of the conventional power storage device 15. The solid line indicates a change in SOC of the power storage device 15 after the countermeasure of this embodiment. As shown in FIGS. 3 and 4, conventionally, the power storage device 15 is not charged when peak-cut is required, and therefore, SOC of the power storage device 15 is flat from 6:00 to 9:00. Since the power storage device 15 is discharged after 10:00, SOC of the power storage device 15 becomes 0% at 15:00.

After the measures in this embodiment, SOC of the power storage device 15 is increased since the power storage device 15 is charged from 6:00 to 9:00. After 10:00, the power storage device 15 is discharged in the same manner as in the related art. Since the power demand of the air conditioner 13 decreases after 15:00, the decrease in SOC becomes gradual. Since SOC of the power storage device 15 is not exhausted even after 15:00, the target demand can be maintained.

### Modifications

(1) In the above-described embodiment, as illustrated in FIG. 1, the facility is the house 10. However, the present disclosure is not limited thereto, and the facility may be another facility or a business establishment that performs some kind of business.
(2) In the above-described embodiment, as illustrated in FIGS. 1 and 2, the power storage device 15 is charged, and the electric power charged in the power storage device 15 is used in another electric device different from the power storage device 15. However, the present disclosure is not limited thereto, and electrified vehicle 40 battery 42 may be charged in place of the power storage device 15 or together with the power storage device 15, and the electric power charged in the battery 42 may be used in an electric device of a facility such as the house 10.

### Summary

(1) As illustrated in FIG. 1, the power storage system is a system including a power storage device 15 provided in a facility such as a house 10 that receives power purchased from a power system such as the power grid 20, a power demand device (for example, the air conditioner 13, the heat pump water heater 14, the charging/discharging device 17, and electrified vehicle 40) that differs from the power storage device 15, and a HEMS controller 100 that manages the use of power in the power storage device 15 and the power demand device. As illustrated in FIG. 1, HEMS controllers include a processor such as a CPU of the control unit 110. As illustrated in FIG. 2, after limiting (e.g., S122) the use of the purchased electric power in the demanding device, the processor controls (e.g., S125) to charge the power storage device when the remaining capacity stored in the power storage device 15 is equal to or less than a predetermined value (e.g., when the remaining capacity is YES in S124).

Thus, the power storage device 15 is charged when the remaining capacity stored in the power storage device 15 is equal to or less than a predetermined value after restricting the use of the purchased power in the device having a power different from the power storage device 15 provided in the facility. As a result, more electric power can be stored in the power storage device 15 in preparation for the peak cut of the purchased electric power in the facility.
(2) As shown in FIG. 2, the processor may control (e.g., S122) to restrict the use of purchased power at the consumer device when peak-cutting of purchased power is required at the facility (e.g., when YES at S121).

This makes it possible to more reliably store more electric power in the power storage device 15 in preparation for the peak cut of the purchased electric power in the facility.
(3) As illustrated in FIG. 2, the processor may control the power storage device 15 to be charged (for example, S125) in a case where the power demand in the demand device is less than the first predetermined power (for example, in a case of YES in S123) and in a case where the remaining capacity stored in the power storage device 15 is equal to or less than a predetermined value (for example, in a case of YES in S124) after limiting the use of the purchased power in the demand device.

This makes it possible to more reliably store more electric power in the power storage device 15 in preparation for the peak cut of the purchased electric power in the facility.
(4) As illustrated in FIG. 2, after limiting the use of the purchased electric power in the demanding device, the processor may perform control to discharge the electric power from the power storage device (for example, S127) when the electric power demand in the demanding device is equal to or higher than the predetermined second electric power (for example, the predetermined value H2) equal to or higher than the predetermined first electric power (for example, the predetermined value L2) (for example, when the electric power is YES in S126).

Thus, even when the use of the purchased electric power in the demanding device is restricted, the electric power can be appropriately supplied to the demanding device.
(5) As shown in FIG. 2, the processor may control (e.g., S111) to charge the power storage device 15 when the peak-cut of the used power is not required in the facility (e.g., in the case of YES in S116), when the power storage device 15 needs to be charged (e.g., in the case of S112 and YES), and when the power demand in the demand device is not less than the predetermined third power (e.g., in the case of S113 and NO), after controlling (e.g., S114) to limit the use of the purchased power in the demand device, when the power demand in the demand device becomes less than the predetermined third power (e.g., in the case of S115 and YES).

Accordingly, more electric power can be stored in the power storage device 15 in preparation for the peak cut of the purchased electric power in the facility.

The embodiment disclosed herein shall be construed as exemplary and not restrictive in all respects. The scope of the present disclosure is shown by the claims rather than by the above description of the embodiments, and is intended to include all modifications within the meaning and scope equivalent to those of the claims.

What is claimed is:

1. An electricity storage system comprising:
an electricity storage device that is provided in a facility that receives supply of purchased electricity from an electricity system;
an electricity demanding device that is different from the electricity storage device, and
a management device that manages use of electricity in the electricity storage device and the demanding device, wherein
the management device includes a processor, and
the processor performs control such that the electricity storage device is charged when a remaining capacity stored in the electricity storage device is equal to or less than a predetermined value after use of the purchased electricity in the demanding device is restricted.

2. The electricity storage system according to claim 1, wherein the processor performs control such that the use of the purchased electricity in the demanding device is restricted when a peak shaving of the purchased electricity is required at the facility.

3. The electricity storage system according to claim 2, wherein the processor performs control such that the electricity storage device is charged in a case where an electricity demand in the demanding device is less than a predetermined first electricity and in a case where a remaining capacity stored in the electricity storage device is equal to or less than a predetermined value after the use of the purchased electricity in the demanding device is restricted.

4. The electricity storage system according to claim 3, wherein the processor performs control such that electricity is discharged from the electricity storage device when the electricity demand in the demanding device is equal to or higher than a predetermined second electricity equal to or greater than the predetermined first electricity after the use of the purchased electricity in the demanding device is restricted.

5. The electricity storage system according to claim 1, wherein the processor performs control such that the electricity storage device is charged when a peak shaving of electricity consumption is not required in the facility, when the electricity storage device needs to be charged, when the electricity demand in the demanding device is not less than a predetermined third electricity, and when the electricity demand in the demanding device becomes less than the predetermined third electricity after performing control to restrict the use of the purchased electricity in the demanding device.
